(19) United States
(12) Patent Application Publication
(10) Pub. No.: US 2024/0215314 A1
(43) Pub. Date: Jun. 27, 2024

(54) THIN FILM TRANSISTOR SUBSTRATE AND METHOD OF MANUFACTURING THE SAME AND DISPLAY APPARATUS COMPRISING THE SAME

(71) Applicant: LG Display Co., Ltd., Seoul (KR)

(72) Inventors: Younghyun KO, Paju-si (KR); ChanYong JEONG, Paju-si (KR)

(21) Appl. No.: 18/458,848

(22) Filed: Aug. 30, 2023

(30) Foreign Application Priority Data
Dec. 26, 2022 (KR) 10-2022-0183906

(51) Int. Cl. H10K 59/121; H10K 59/12; H10K 59/126

(52) U.S. Cl. CPC H10K 59/1213; H10K 59/1201; H10K 59/1216; H10K 59/126

(57) ABSTRACT

Disclosed is a thin film transistor substrate including a first thin film transistor having a first gate electrode, a first active layer, a first source electrode, and a first drain electrode, and a second thin film transistor having a second gate electrode, a second active layer with a pattern different from a pattern of the first active layer, a second source electrode, and a second drain electrode. The first active layer includes a first lower active layer overlapping the first gate electrode and a first upper active layer disposed on the first lower active layer and not overlapping the first gate electrode. The second active layer includes a second lower active layer overlapping the second gate electrode and a second upper active layer disposed on the second lower active layer and overlapping the second gate electrode. A display apparatus including the same thin film transistor substrate is also disclosed.

### CROSS-REFERENCE TO RELATED APPLICATIONS

This application claims the benefit of the Korean Patent Application No. 10-2022-0183906 filed on Dec. 26, 2022, which is hereby incorporated by reference as if fully set forth herein.

### BACKGROUND

### Technical Field

The present disclosure relates to a thin film transistor substrate, a method of manufacturing the same, and a display apparatus including the same.

### Description of the Related Art

Since thin film transistors can be manufactured on glass or plastic substrates, they are widely used as switching devices or driving devices for displays such as liquid crystal display apparatus or organic light emitting devices.

In general, it may be advantageous for switching thin film transistors used in display apparatus to have large on-current (Ion) to improve on-off characteristics, and for driving thin film transistors used in display apparatus to have large s-factors for gray scale expression.

### BRIEF SUMMARY

However, the on-current and the S-factor generally have a trade-off relationship. Accordingly, increasing the on-current tends to reduce the S-factor and increasing the S-factor tends to reduce the on-current. Therefore, a method of efficiently forming one thin film transistor with a large S-factor and another thin film transistor with a large on current on the same substrate is beneficial.

Various embodiments of the present disclosure has been made in view of the various technical problems in the related art including the above-identified problems. Various embodiments of the present disclosure provide a thin film transistor substrate with a first thin film transistor that can be easily used for a driving thin film transistor due to its large S-factor and a second thin film transistor that can be easily used for a switching thin film transistor, and a display apparatus including the same.

In accordance with an aspect of the present disclosure, the above and other objects can be accomplished by the provision of a thin film transistor substrate comprising: a substrate; a first thin film transistor disposed on the substrate, and including a first gate electrode, a first active layer, a first source electrode, and a first drain electrode; and a second thin film transistor disposed on the substrate, and including a second gate electrode, a second active layer with a pattern different from a pattern of the first active layer, a second source electrode and a second drain electrode, wherein the first active layer includes a first lower active layer overlapping the first gate electrode and a first upper active layer disposed on the first lower active layer and not overlapping the first gate electrode, and the second active layer includes a second lower active layer overlapping the second gate electrode and a second upper active layer disposed on the second lower active layer and overlapping the second gate electrode, and a display apparatus including the same.

In accordance with an aspect of the present disclosure, the present disclosure provides a thin film transistor substrate comprising: a substrate; a first thin film transistor disposed on the substrate, and including a first gate electrode, a first active layer, a first source electrode, and a first drain electrode; and a second thin film transistor disposed on the substrate, and including a second gate electrode, a second active layer with a pattern different from a pattern of the first active layer, a second source electrode and a second drain electrode, wherein the first active layer includes a first lower active layer and two first upper active layers disposed to be spaced apart from each other on one side and another side of the first lower active layer, and the second active layer includes a second lower active layer and a second upper active layer disposed on the second lower active layer and having a same shape as the second lower active layer, and a display apparatus including the same.

In accordance with an aspect of the present disclosure, the present disclosure provides a method of manufacturing a thin film transistor substrate comprising: a process of sequentially forming a lower active layer and an upper active layer on a substrate; a process of forming a first active layer of a first thin film transistor and a second active layer of a second thin film transistor by patterning the lower active layer and the upper active layer; a process of forming a gate insulating layer on the first active layer and the second active layer; a process of etching a portion of the gate insulating layer to form a first contact hole exposing a portion of the first active layer and a second contact hole exposing a portion of the second active layer; and a process of forming a first gate electrode overlapping the first active layer, a second gate electrode overlapping the second active layer, a first connection electrode connected to the first active layer through the first contact hole, and a second connection electrode connected to the second active layer through the second contact hole on the gate insulating layer, wherein the process of forming the first active layer includes a process of forming a first lower active layer and two first upper active layers to be spaced apart from each other on one side and another side of the first lower active layer, and the process of forming the second active layer includes a process of forming a second lower active layer and a second upper active layer in the same shape as the second lower active layer on the second lower active layer.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1A is a plan view of a display apparatus according to an embodiment of the present disclosure.

FIG. 1B is a cross-sectional view of a thin film transistor substrate according to an embodiment of the present disclosure.

FIG. 2 is a cross-sectional view of a thin film transistor substrate according to another embodiment of the present disclosure.

FIG. 3 is a cross-sectional view of a thin film transistor substrate according to another embodiment of the present disclosure.

FIG. 4 is a cross-sectional view of a thin film transistor substrate according to another embodiment of the present disclosure.

FIG. 5 is a cross-sectional view of a thin film transistor substrate according to another embodiment of the present disclosure.

FIG. 6 is a cross-sectional view of a thin film transistor substrate according to another embodiment of the present disclosure.

FIG. 7 is a cross-sectional view of a thin film transistor substrate according to another embodiment of the present disclosure.

FIG. 8 is a cross-sectional view of a thin film transistor substrate according to another embodiment of the present disclosure.

FIGS. 9A to 9H are cross-sectional views illustrating a manufacturing process of a thin film transistor substrate according to an embodiment of the present disclosure.

FIGS. 10A to 10H are cross-sectional views illustrating a manufacturing process of a thin film transistor substrate according to another embodiment of the present disclosure.

FIG. 11 is a cross-sectional view of a display apparatus according to an embodiment of the present disclosure.

FIG. 12 is a schematic diagram of a display apparatus according to an embodiment of the present disclosure.

FIG. 13 is a circuit diagram of one pixel provided in a display apparatus according to an embodiment of the present disclosure.

FIG. 14 is a circuit diagram of one pixel provided in a display apparatus according to another embodiment of the present disclosure.

FIG. 15 is a circuit diagram of one pixel provided in a display apparatus according to another embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, dimensions (e.g., length, width, height, thickness, radius, diameter, area, etc.), ratios, angles, and number of elements disclosed in the drawings for describing embodiments of the present disclosure are merely examples, and thus the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

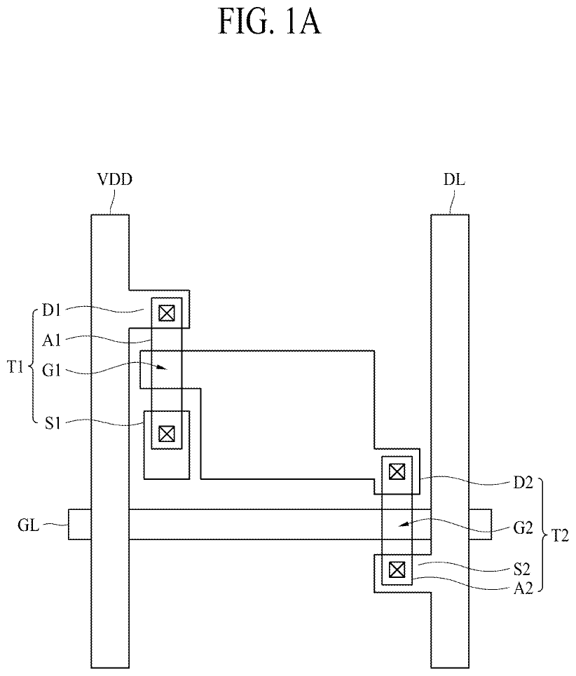

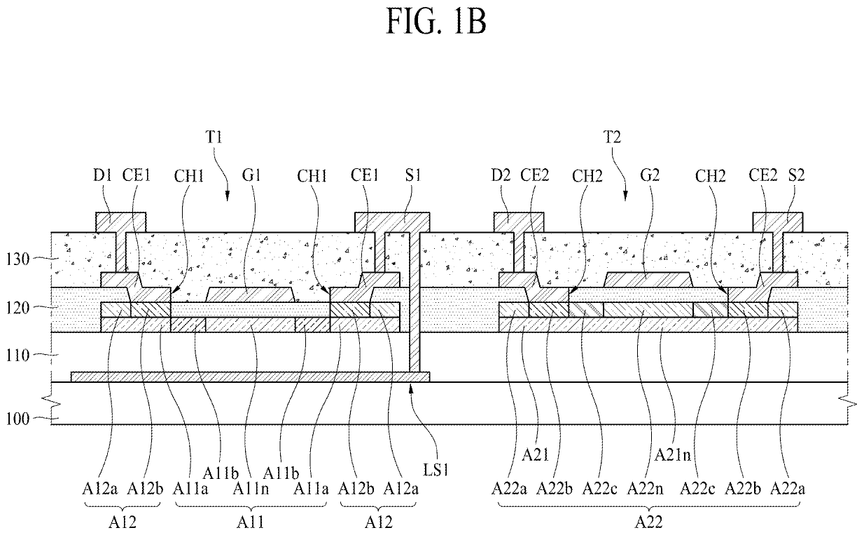

FIG. 1A is a plan view of a display apparatus according to an embodiment of the present disclosure, which shows the appearance of the first thin film transistor T1 and the second thin film transistor T2 provided in one pixel.

As shown in FIG. 1A, a display apparatus according to an embodiment of the present disclosure includes a gate line GL, a data line DL, a power line VDD, a first thin film transistor T1, and a second thin film transistor T2.

The gate line GL extends in a first direction, for example, in a horizontal direction.

The data line DL and the power line VDD extend in a second direction, for example, in a vertical direction, and are spaced apart from each other.

The first thin film transistor T1 can function as a driving thin film transistor and includes a first gate electrode G1, a first active layer A1, a first source electrode S1, and a first drain electrode D1.

The first gate electrode G1 is electrically connected to a second drain electrode D2 of the second thin film transistor T2. The first gate electrode G1 may be integrally formed with the second drain electrode D2, but is not limited thereto.

The first active layer A1 overlaps the first gate electrode G1 in its central area, and overlaps the first source electrode S1 and the first drain electrode D1 in both end areas of the first active layer A1. Although not illustrated, a light shielding layer may be additionally formed to prevent light from entering the first active layer A1 by overlapping the entire region of the first active layer A1.

The first source electrode S1 and the first drain electrode D1 are formed to face each other. The first source electrode S1 is electrically connected to an anode electrode (not shown), and the first drain electrode D1 is electrically connected to the power line VDD. In some cases, the first source electrode S1 may be electrically connected to the power line VDD, and the first drain electrode D1 may be electrically connected to the anode electrode (not shown).

The second thin film transistor T2 can function as a switching thin film transistor and includes a second gate electrode G2, a second active layer A2, a second source electrode S2, and a second drain electrode D2.

The second gate electrode G2 may be formed as a portion of the gate line GL, but is not limited thereto, and may protrude from the gate line GL.

The second active layer A2 overlaps the second gate electrode G2 in its central area, and overlaps the second source electrode S2 and the second drain electrode D2 in both end areas of the second active layer A2.

The second source electrode S2 and the second drain electrode D2 are formed to face each other. The second source electrode S2 may protrude from the data line DL, but is not limited thereto and may be formed as a portion of the data line DL.

The second drain electrode D2 may be electrically connected to the first gate electrode G1 of the first thin film transistor T1.

FIG. 1B is a cross-sectional view of a thin film transistor substrate according to an embodiment of the present disclosure.

As shown in FIG. 1B, the thin film transistor substrate according to an embodiment of the present disclosure comprises a substrate 100, a first thin film transistor T1, and a second thin film transistor T2.

The substrate 100 may be made of glass or plastic. In particular, the substrate 100 may be made of a transparent plastic having flexible properties, for example polyimide. When the polyimide is used as the substrate 100, a heat resistant polyimide that can withstand high temperatures may be used, considering that a high-temperature deposition process is performed on the substrate 100

The first thin film transistor T1 includes a first light shielding layer LS1, a first active layers A11 and A12, a first gate electrode G1, a first connection electrode CE1, a first source electrode S1, and a first drain electrode D1. In this case, the first gate electrode G1 is provided above the first active layers A11, A12, and accordingly, the first thin film transistor T1 has a top gate structure.

The first light shielding layer LS1 is formed on the substrate 100. The first light shielding layer LS1 may be formed to overlap the first active layers A11 and A12 to prevent external light from being incident into the first active layers A11 and A12. The first light shielding layer LS1 may be formed to overlap an entire area of the first active layers A11 and A12. The first light shielding layer LS1 is made of a conductive material and can be electrically connected to the first source electrode S1. The first light shielding layer LS1 can be functioned as a capacitor electrode. The first light shielding layer LS1 and the first gate electrode G1 may configure the capacitor.

The first active layers A11 and A12 are provided on the first light shielding layer LS1. Specifically, a buffer layer 110 is provided on the first light shielding layer LS1, and the first active layers A11 and A12 are provided on the buffer layer 110.

The first active layers A11 and A12 are including a first lower active layer A11 and a first upper active layer A12. The first lower active layer A11 is provided on the buffer layer 110, and the first upper active layer A12 is provided on the first lower active layer A11.

Each of the first lower active layer A11 and the first upper active layer A12 comprises a semiconductor material, for example an oxide semiconductor material.

In this case, an oxide semiconductor material included in the first lower active layer A11 may have better stability than the oxide semiconductor material included in the first upper active layer A12, and an oxide semiconductor material included in the first upper active layer A12 may have greater carrier mobility than the oxide semiconductor material included in the first lower active layer A11.

As an example, the oxide semiconductor material included in the first upper active layer A12 with a large carrier mobility is at least one of IGZO(InGaZnO)-based oxide semiconductor material, IZO(InZnO)-based oxide semiconductor material, IGZTO(InGaZnSnO)-based oxide semiconductor material, ITZO(InSnZnO)-based oxide semiconductor material, FIZO(FeInZnO)-based oxide semiconductor material, ZnO-based oxide semiconductor material, SIZO(SiInZnO)-based oxide semiconductor material, and ZnON(Zn-Oxynitride)-based oxide semiconductor material.

The oxide semiconductor material included in the first lower active layer A11 having excellent stability is at least one of a IGZO(InGaZnO)-based oxide semiconductor material, GZO(GaZnO)-based oxide semiconductor material, IGO(InGaO)-based oxide semiconductor material, and GZTO(GaZnSnO)-based oxide semiconductor material.

When the first upper active layer A12 and the first lower active layer A11 are made of IGZO(InGaZnO)-based oxide semiconductor material, a concentration of indium of the first upper active layer A12 is greater than that of the first lower active layer A11.

The first lower active layer A11 may include the first channel part A11n, the first connection part A11a, and the first lower conductive part A11b.

The first channel part A11n is made of a semiconductor material and overlaps with the first gate electrode G1 and may be protected by the first gate electrode G1. The first channel part A11n may comprise an oxide semiconductor material.

The first connection part A11a may be provided on one side and another side of the first channel part A11n. As an example, one first connection part A11a is provided on the right side of the first channel part A11n, and another first connection part A11a may be provided on the left side of the first channel part A11n.

The first connection part A11a may not overlap the first gate electrode G1, and may be formed to be overlapped with the first upper active layer A12 and the first connection electrode CE1. The first connection part A11a may be made of the same semiconductor material as the channel part A11n, for example an oxide semiconductor material.

The first lower conductive part A11b is provided between the first channel part A11n and the first connection part A11a. Specifically, one of the first lower conductive part A11b is provided between the first channel part A11n and the first connection part A11a, and another one of the first lower conductive part A11b is provided between the first channel part A11n and the first connection part A1a.

The first lower conductive part A11b is not overlapped with the first gate electrode G1 and the first connection electrode CE1, and may be formed to overlap a region spaced apart between the first gate electrode G1 and the first connection electrode CE1. Impurities may penetrate into a region spaced apart between the first gate electrode G1 and the first connection electrode CE1 by an ion doping process performed using the first gate electrode G1 and the first connection electrode CE1 as a mask to form the first lower conductive part A11b. The first lower conductive part A11b may be formed by doping a semiconductor material constituting the first channel part A11n with impurities. Accordingly, the first lower conductive part A11b may have better electrical conductivity than the first channel part A11n. In addition, the first lower conductive part A11b may have better electrical conductivity than the first connection part A11a.

The first upper active layer A12 is made of different patterns from the first lower active layer A11.

The two first upper active layers A12 are spaced apart from each other while facing each other with the gate insulating layer 120 interposed therebetween, and each of the first upper active layer A12 is provided between the first lower active layer A11 and the first connection electrode CE1. Specifically, a bottom surface of the first upper active layer A12 is in contact with a top surface of the first lower active layer A11 and a top surface of the first upper active layer A12 is in contact with a bottom surface of the first connection electrode CE1.

The first upper active layer A12 may be formed to be in contact with the first connection electrode CE1 and not to be in contact with the first gate electrode G1. In addition, the first upper active layer A12 may be formed not to be in contact with a region separated between the first connection electrode CE1 and the first gate electrode G1.

The first upper active layer A12 is formed to be in contact with the first connection part A1a of the first lower active layer A11, and is formed not to be in contact with the first channel A11n and the first conductive part A11b of the first lower active layer A11.

The first upper active layer A12 may comprise an oxide semiconductor material.

The first upper active layer A12 includes a first upper conductive part A12b and a first upper non-conductive part A12a. The first upper conductive part A12b may have a better electrical conductivity than the first upper non-conductive part A12a.

A top surface of the first upper conductive part A12b is contacted with the first connection electrode CE1, but a top surface of the first upper non-conductive part A12a may not be in contact with the first connection electrode CE1. A bottom surface of the first upper conductive part A12b and a bottom surface of the first upper non-conductive part A12a may be in contact with the first connection part A11a of the lower active layer A11. In addition, the first upper conductive part A12b is formed to contact the first lower conductive part A11b of the first lower active layer A11, and thus carriers, for example, electrons may move between the first lower conductive part A11b and the first connection electrode CE1 through the first upper conductive part A12b.

The first upper conductive part A12b may be overlapped with a first contact hole CH1 of the gate insulating layer 120, and the first upper non-conductive part A12a may not be overlapped with the first contact hole CH1 of the gate insulating layer 120.

The first upper conductive part A12b may be formed by the effect of the plasma at the time of etching process forming the first contact hole CH1 of the gate insulating layer 120. In some cases, the first upper conductive part A12b may be formed through a separate ion doping process after the first contact hole CH1 of the gate insulating layer 120 is formed.

One of the first upper non-conductive part A12a is connected to one side of the first upper conductive part A12b, for example, a right side, and another one of the first upper non-conductive part A12a is connected to another side of the first upper conductive part A12b, for example, a left side. In some cases, the first upper non-conductive part A12a may be omitted. That is, when the first contact hole CH1 of the gate insulating layer 120 expands to the region of the first upper non-conductive part A12a, the region of the first upper non-conductive part A12a may be substituted with the first upper conductive part A12b.

The first gate electrode G1 is provided on the gate insulating layer 120. The first gate electrode G1 may be overlapped with the first channel part A11 of the first lower active layer A11, and may not be overlapped with the first connection part A11a and the first lower conductive part A11b of the first lower active layer A11. In addition, the first gate electrode G1 may not be overlapped with the first upper active layer A12.

The first connection electrode CE1 is provided on the gate insulating layer 120. The first connection electrode CE1 may be made of the same material on the same layer as the first gate electrode G1.

The two first connection electrodes CE1 are spaced apart from each other with the first gate electrode G1 interposed therebetween. One of the first connection electrodes CE1 is connected to the first source electrode S1, and another the first connection electrodes CE1 is connected to the first drain electrode D1.

Each of the two first connection electrodes CE1 may be connected to the first upper active layer A12, in particular, the first upper conductive part A12b of the first upper active layer A12 through the first contact hole CH1 provided in the gate insulating layer 120.

The first source electrode S1 and the first drain electrode D1 are provided on the interlayer insulating layer 130.

The first source electrode S1 may be connected to the first connection electrode CE1 through a contact hole (not shown) provided in the interlayer insulating layer 130. Accordingly, the first source electrode S1 may be electrically connected to the one first upper active layer A12 through the one first connection electrode CE1. In addition, the first source electrode S1 may be electrically connected to the first light shielding layer LS1 through a contact hole (not shown) provided in the buffer layer 110, the gate insulating layer 120 and the interlayer insulating layer 130.

The first drain electrode D1 may be connected to the another first connection electrode CE1 through a contact hole (not shown) provided in the interlayer insulating layer 130. Accordingly, the first drain electrode D1 may be electrically connected to the another first upper active layer A12 through the another first connection electrode CE1.

According to an embodiment of the present disclosure, since the first active layers A11 and A12 include a first lower active layer A11 and a first upper active layer A12, and one side and another side of the first lower active layer A11 is formed to be apart from the first upper active layer A12, a main channel for moving carriers, for example, electrons becomes the first lower active layer A11.

In this case, since the mobility of the semiconductor material constituting the first lower active layer A11 is configured to be smaller than the mobility of the semiconductor material constituting the first upper active layer A12, the electronic movement in the first lower active layer A11 can be adjusted, thereby improving the S-factor of the first thin film transistor T1.

The sub-threshold swing; s-factor can be used as an indicator of the degree of change in the drain-source current IDS to the gate voltage VGS in the threshold voltage Vth section of the thin film transistors T1, T2.

Such an S-factor is obtained as the reciprocal value of the slope of the graph in the threshold voltage Vth section in the drain-source current graph for the gate voltage of the thin film transistors T1, T2. Therefore, when the S-factor increases, the drain-source current change rate for the gate voltage becomes gentle in the threshold voltage Vth section, and when the S-factor decreases, the drain-source current change rate for the gate voltage increases rapidly in the threshold voltage Vth section. In other words, if the slope of the drain-source current graph is large, the S-factor is small, and if the slope of the drain-source current graph is small, the S-factor is large.

When the S-factor increases, the change rate of the drain-source current to the gate voltage in the threshold voltage Vth section becomes gentle, so it becomes easy to adjust the magnitude of the drain-source current through the adjustment of the gate voltage. In a display apparatus driven by current, for example, an organic light emitting display apparatus, the gradation of a pixel can be controlled by adjusting the magnitude of the drain-source current of the driving thin film transistor. In this case, the magnitude of the drain-source current of the driving thin film transistor is determined by the gate voltage. Therefore, in an organic light emitting display apparatus driven by current, the larger the S-factor of the driving thin film transistor driving TFT, the easier it is to adjust the gray scale of the pixel.

According to an embodiment of the present disclosure, since the mobility of the semiconductor material constituting the first lower active layer A11 is configured to be smaller than the mobility of the semiconductor material constituting the first upper active layer A12, the S-factor of the first thin film transistor T1 may increase because electron mobility is reduced in the main channel of electron movement, and accordingly, the first thin film transistor T1 may be easily used as a driving thin film transistor.

Accordingly, the first thin film transistor T1 may be made of a drive thin film transistor in the display area.

The second thin film transistor T2 includes second active layer A21 and A22, a second gate electrode G2, a second connection electrode CE2, a second source electrode S2 and a second drain electrode D2. In this case, the second gate electrode G2 is provided above the second active layers A21 and A22, and accordingly, the second thin film transistor T2 has a top gate structure.

The second active layers A21 and A22 are provided on the buffer layer 110. The second active layers A21 and A22 may be provided on the same layer as the first active layers A11 and A12.

The second active layers A21 and A22 include a second lower active layer A21 and a second upper active layer A22. The second lower active layer A21 is provided on the buffer layer 110, and the second upper active layer A22 is provided on the second lower active layer A21.

The second lower active layer A21 of the second active layers A21 and A22 includes the same semiconductor material on the same layer as the first lower active layer A11 of the first active layers A11 and A12. The second upper active layer A22 of the second active layers A21 and A22 includes the same semiconductor material on the same layer as the first upper active layer A12 of the first active layers A11 and A12.

Therefore, the oxide semiconductor material included in the second lower active layer A21 may have a better stability than the oxide semiconductor material included in the second upper active layer A22, and the oxide semiconductor material included in the second upper active layer A22 may have greater carrier mobility than the oxide semiconductor material included in the second lower active layer A21.

As an example, the oxide semiconductor material included in the second upper active layer A22 with a large carrier mobility is at least one of a IGZO(InGaZnO)-based oxide semiconductor material, IZO(InZnO)-based oxide semiconductor material, IGZTO(InGaZnSnO)-based oxide semiconductor material, ITZO(InSnZnO)-based oxide semiconductor material, FIZO(FeInZnO)-based oxide semiconductor material, ZnO-based oxide semiconductor material, SIZO(SiInZnO)-based oxide semiconductor material, and ZnON(Zn-Oxynitride)-based oxide semiconductor material.

The oxide semiconductor material included in the second lower active layer A21 having excellent stability is at least one of a IGZO(InGaZnO)-based oxide semiconductor material, GZO(GaZnO)-based oxide semiconductor material, IGO(InGaO)-based oxide semiconductor material, and GZTO(GaZnSnO)-based oxide semiconductor material.

When the second upper active layer A22 and the second lower active layer A21 are made of IGZO(InGaZnO)-based oxide semiconductor material, the concentration of indium In of the second upper active layer A22 is greater than the concentration of indium In of the second lower active layer A21.

The second lower active layer A21 may be provided not to include a separate conductive part. The second lower active layer A21 may include a third channel part A21n in a region overlapped with the second gate electrode G2.

The second upper active layer A22 may be made of the same shape as the second lower active layer A21.

The second upper active layer A22 includes a second channel part A22n, a second upper conductive part A22b, a third upper conductive part A22c, and a second upper non-conductive part A22a.

The second channel part A22n is made of a semiconductor material and overlaps the second gate electrode G2 and may be protected by the second gate electrode G2. The second channel part A22n may comprise an oxide semiconductor material.

The two upper conductive part A22b may be provided on one side and another side of the second channel part A22n. Specifically, one of the second upper conductive part A22b is provided on the one side, for example, the right side of the second channel part A22n, and another one of the second upper conductive part A22b is provided on the another side, for example, the left side of the second channel part A22n.

The top surface of the second upper conductive part A22b may be in contact with the second connection electrode CE1. In addition, the second upper conductive part A22b may be overlapped with a second contact hole CH2 of the gate insulating layer 120. Accordingly, the second upper conductive part A22b may be formed by the plasma at the time of etching process forming the second contact hole of the gate insulating layer 120. In some cases, the second upper conductive part A22b may be formed through a separate ion doping process after the second contact hole CH2 of the gate insulating layer 120 is formed. Accordingly, the second upper conductive part A22b may comprise a semiconductor material constituting the second channel part A22n and may be formed by doping the impurities in the semiconductor material.

The two upper conductive parts A22c may be provided between the second channel part A22n and the second upper conductive part A22b. Specifically, one of the third upper conductive part A22c is provided between the second channel part A22n and the one second upper conductive part A22b, and another one of the third upper conductive part A22c may be provided between the second channel part A22n and the another second upper conductive part A22b.

Each of the two third upper conductive parts A22c may be formed by doping the impurities in a semiconductor material constituting the second channel part A22n.

The third upper conductive part A22c is formed through a different process with the second upper conductive part A22b. Accordingly, the third upper conductive part A22c may be different from the second upper conductive part A22b in terms of the type and concentration of the doped impurities.

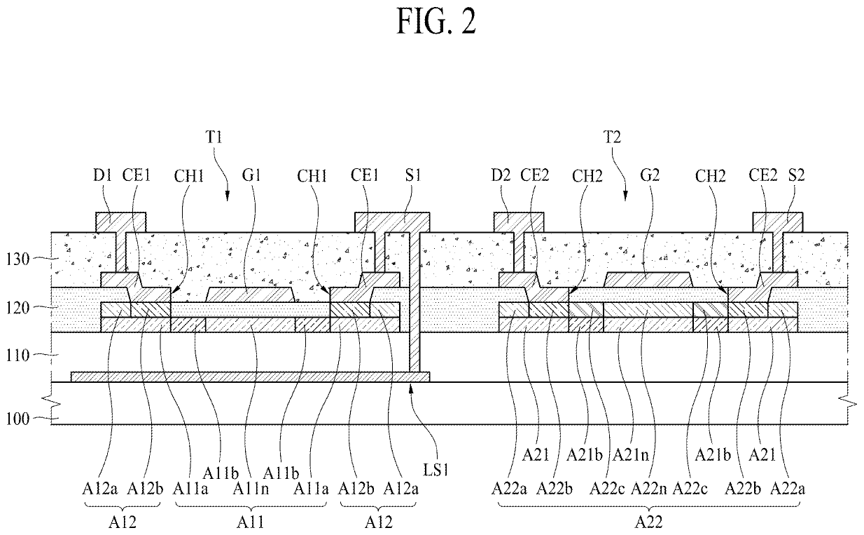

The third upper conductive part A22c does not overlap the second gate electrode G2 and the second connection electrode CE2, and overlaps a region spaced apart between the second gate electrode G2 and the second connection electrode CE2. Impurities may penetrate into the region spaced apart between the second gate electrode G2 and the second connection electrode CE2 by an ion doping process performed using the second gate electrode G2 and the second connection electrode CE2 as a mask to form the third upper conductive part A22c. Further, as shown in various figures including FIGS. 1B, 2, the third upper conductive part A22c does not overlap the second gate electrode G2 both vertically and horizontally. That is, the third upper conductive part A22c does not overlap with the second gate electrode G2 from a plan view (e.g., vertical direction). Further, the third upper conductive part A22c is not disposed at the same layer as the second gate electrode G2. Accordingly, the third upper conductive part A22c does not overlap with the second gate electrode G2 in a vertical direction.

In some embodiments, as indicated by the dimensions shown in, for example, FIG. 2, a width of the second lower conductive part A21b is the same or substantially the same as a width of the third upper conductive part A22c.

The third upper conductive part A22c and the second upper conductive part A22b may have better electrical conductivity than the second channel part A22n. In addition, the third upper conductive part A22c and the second upper conductive part A22b may have better electrical conductivity than the second upper conductive part A22a.

One of the second upper non-conductive part A22a is connected to one side, for example, the right side of the one second upper conductive part A22b, and another one of the second upper non-conductive part A22a is connected to another side, for example, the left side of the another second upper conductive part A22b. In some cases, the second upper non-conductive part A22a may be omitted. That is, when the second contact hole CH2 of the gate insulating layer 120 extends to a region of the second upper non-conductive part A22a, the region of the second upper non-conductive part A22a may be substituted with the second upper conductive part A22b.

The second gate electrode G2 is provided on the gate insulating layer 120.

The second gate electrode G2 may be made of the same material as the first gate electrode G1.

The second gate electrode G2 may overlap the second channel part A22n of the second upper active layer A22, and may not overlap the second upper conductive part A22b of the second upper active layer A22, the third upper conductive part A22c, and the second upper non-conductive part A22a.

The second connection electrode CE2 is provided on the gate insulating layer 120.

At least a portion of the second connection electrode CE2 may consist of the same material on the same layer as the first connection electrode CE1. In addition, the at least a portion of the second connection electrode CE2 may consist of the same material on the same layer as the second gate electrode G2.

The two second connection electrodes CE2 are spaced apart from each other with the second gate electrode G2 interposed therebetween. The one second connection electrode CE2 is connected to the second source electrode S2, and the another second connection electrode CE2 is connected to the second drain electrode D2.

Each of the two second connection electrodes CE2 may be connected to the second upper active layer A22, in particular, the second upper conductive part A22b of the second upper active layer A22 through the second contact hole CH2 provided in the gate insulating layer 120.

The second source electrode S2 and the second drain electrode D2 are provided on the interlayer insulating layer 130.

The second source electrode S2 and the second drain electrode D2 may consist of the same material on the same layer as the first source electrode S1 and the first drain electrode D1.

The second source electrode S2 may be connected to the one second connection electrode CE2 through a contact hole (not shown) provided in the interlayer insulating layer 130. Accordingly, the second source electrode S2 may be electrically connected to the one second upper active layer A22 through the one second connection electrode CE2.

The second drain electrode D2 may be connected to the another second connection electrode CE2 through a contact hole (not shown) provided in the interlayer insulating layer 130. Accordingly, the second drain electrode D2 may be electrically connected to the another second upper active layer A22 through the another second connection electrode CE2.

According to an embodiment of the present disclosure, since the second active layers A21 and A22 include a second lower active layer A21 and a second upper active layer A22, and the second upper active layer A22 includes a second upper conductive part A22b and a third upper conductive part A22c having relatively good conductivity, while the second lower active layer A21 does not include a separate conductive part, the main channel of electron movement becomes the second upper active layer A22.

In this case, the mobility of the semiconductor material constituting the second upper active layer A22 is configured to be larger than the mobility of the semiconductor material constituting the second lower active layer A21. As electron mobility increases in the main channel of electron movement, the on-current characteristics of the second thin film transistor T2 can be improved, and accordingly, the second thin film transistor T2 can be easily used as a switching thin film transistor.

Accordingly, the second thin film transistor T2 may be made of a switching thin film transistor in the display area, or may be made of switching thin film transistor in the gate driver in the non-display area.

FIG. 2 is a cross-sectional view of a thin film transistor substrate according to another embodiment of the present disclosure, which is the same as the thin film transistor substrate according to FIG. 1B, except that the second lower active layer A21 of the second thin film transistor T2 has a second lower conductive part A21b. Therefore, the same reference numerals are assigned to the same configuration, and only different configurations will be described below. This is the same in the embodiments below.

As shown in FIG. 2, the second lower active layer A21 further includes a second lower conductive part A21b.

The second lower conductive part A21b may be formed by penetrating impurities into the second lower active layer A21 when forming the third upper conductive part A22c of the second upper active layer A22.

Accordingly, the second lower conductive part A21b may be formed to overlap the third upper conductive part A22c. In addition, the type of impurities of the second lower conductive part A21b may be the same as the type of impurities of the third upper conductive part A22c. However, the concentration of impurities of the second lower conductive part A21b may be less than the concentration of impurities of the third upper conductive part A22c.

Referring to FIG. 2, the first gate insulating layer 120 is not only between the first gate electrode G1 and the first lower active layer A11, but a portion of the first gate insulating layer 120 is also disposed adjacent to the first transistor T1 and the second transistor T2. Accordingly, the portion of the first gate insulating layer 120 covers the side surfaces of A12a and A11a. Similarly, another portion of the first gate insulating layer 120 covers the side surfaces of A12a, A11a, and the side surfaces of A22a, A21.

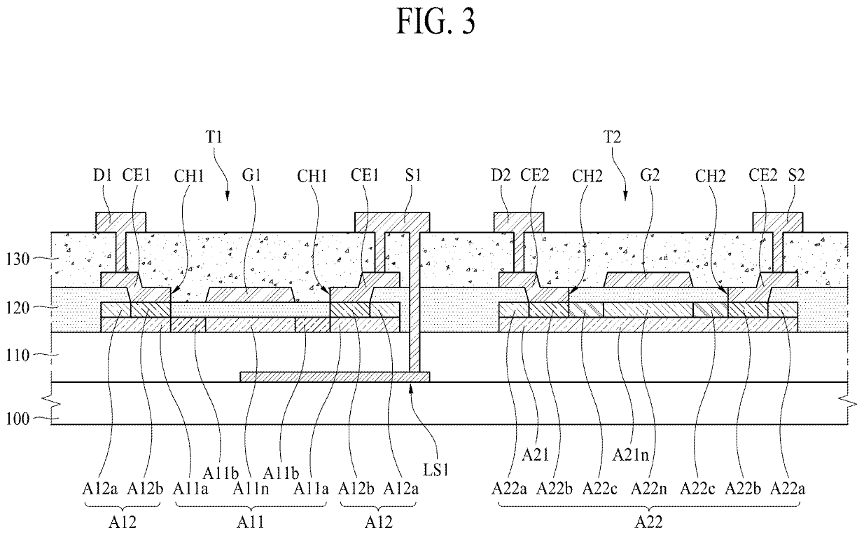

FIG. 3 is a cross-sectional view of a thin film transistor substrate according to another embodiment of the present disclosure. FIG. 3 is the same as the thin film transistor substrate according to FIG. 1B, except that the structure of the first light shielding layer LS1 is changed.

As shown in FIG. 3, the first light shielding layer LS1 is provided to overlap a portion of the first active layers A11 and A12, without overlapping the entire first active layers A11 and A12.

Specifically, the first light shielding layer LS1 is overlapped with the one first lower conductive part A11b provided on one side, for example, the right side of the first channel part A11 and not overlapped with the another first lower conductive part A11b provided on another side, for example, the left side of the first channel part A11. Accordingly, an effective gate voltage Veff applied to the one first lower conductive part A11b may be smaller than an effective gate voltage Veff applied to the another first lower conductive part A11b, and accordingly, the S-factor of the first thin film transistor T1 may be increased.

On the other hand, since the effective gate voltage VEFF applied to the another first lower conductive part A11b is not reduced or reduced less, charge may move smoothly in the ON state of the first thin film transistor T1, so that the on-current of the first thin film transistor T1 is not reduced.

In the conventional case, a method of increasing the distance between the gate electrode and the channel part was applied to increase the S-factor of the thin film transistor. In this case, there is a problem that the S-factor increases but the ON current of the thin film transistor decreases.

On the other hand, according to another embodiment of the present disclosure, since the first light shielding layer LS1 made of a conductive material is overlapped with the one first lower conductive part A11b, the S-factor of the first thin film transistor T1 may be improved, and since the first light shielding layer LS1 is not overlapped with the another first lower conductive part A11b, the ON current of the first thin film transistor may not be decreased.

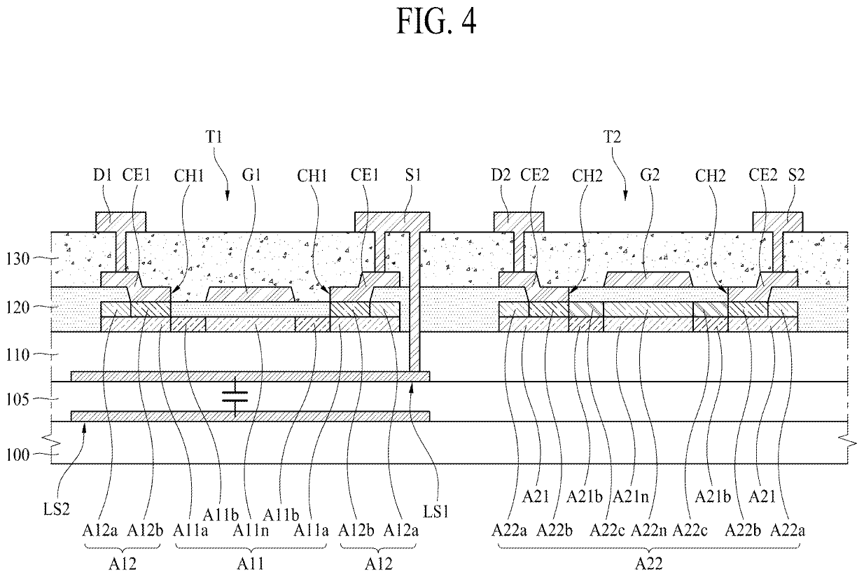

FIG. 4 is a cross-sectional view of a thin film transistor substrate according to another embodiment of the present disclosure. FIG. 4 is the same as the thin film transistor substrate according to FIG. 1B, except that the second light shielding layer LS2 and the additional buffer layer 105 are added.

As shown in FIG. 4, an additional buffer layer 105 is formed under the first light shielding layer LS1, and a second light shielding layer LS2 may be additionally formed under the additional buffer layer 105.

The second light shielding layer LS2 is made of a conductive material, and the capacitor is configured by the first light shielding layer LS1, the additional buffer layer 105, and the second light shielding layer LS2 to increase the capacitor capacity. Although not shown, the second light shielding layer LS2 can be electrically connected to the first gate electrode G1.

The first light shielding layer LS1 formed relatively above may be connected to the first source electrode S1, and the second light shielding layer LS2 formed relatively below may be connected to the first gate electrode G1, but in some cases, the first light shielding layer LS1 formed relatively above may be connected to the first gate electrode G1, and the second light shielding layer LS2 formed relatively below may be connected to the first source electrode S1.

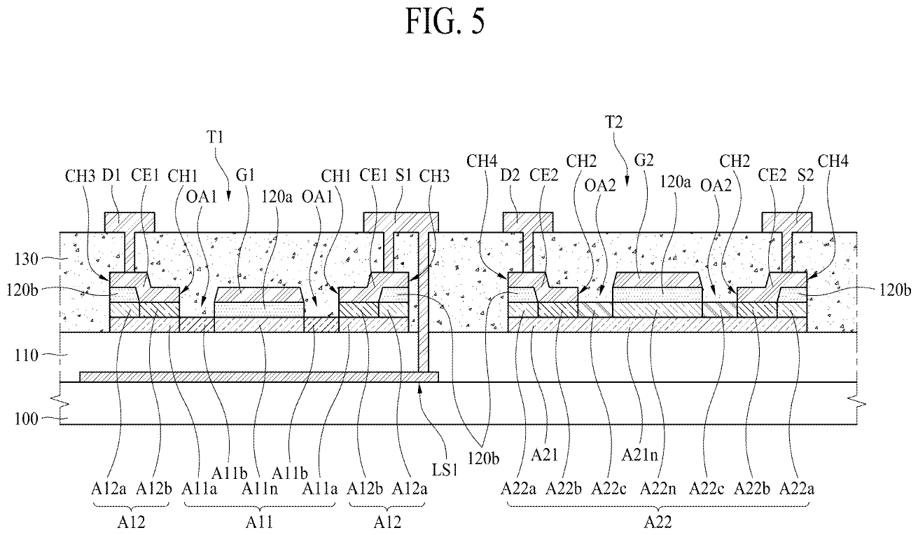

FIG. 5 is a cross-sectional view of a thin film transistor substrate according to another embodiment of the present disclosure. FIG. 5 is different from the thin film transistor substrate according to FIG. 1B in that the structure of the gate insulating layers 120a and 120b is changed.

According to FIG. 1B described above, the gate insulating layer 120 covers the entire top surface of the first active layer A11 and A12 and the entire top surface of the second active layer A21 and A22 except the first contact hole CH1 and the second contact hole CH2, also extend outside the first active layers A11 and A12 and the second active layers A21 and A22. Therefore, in the case of FIG. 1B, the gate insulating layer 120 is provided in an area between the first gate electrode G1 and the first connection electrode CE1 and an area between the second gate electrode G2 and the second connection electrode CE2.

On the other hand, according to FIG. 5, a first gate insulating layer 120a is formed under the gate electrodes G1 and G2, and a second gate insulation layer 120b is formed under the connection electrodes CE1 and CE2, The first gate insulating layer 120a and the second gate insulating layer 120b are spaced apart from each other in the first thin film transistor T1 with the first contact hole CH1 and the first open area OA1, and spaced apart from each other in the second thin film transistor T2 with the second contact hole CH2 and the second open area OA2.

Accordingly, in the case of FIG. 5, The gate insulating layers 120a and 120b are not provided in the area between the first gate electrode G1 and the first connection electrode CE1 and the area between the second gate electrode G2 and the second connection electrode CE2, but the first open area OA1 and the second open area OA2 are provided in that area. In addition, according to FIG. 5, the interlayer insulating layer 130 is in contact with the buffer layer 110.

In this case, the first lower conductive part A11b of the first lower active layer A11 is provided in the first open area OA1, and the third upper conductive part A22c of the second upper active layer A22 is provided in the second open area OA2.

The first lower conductive part A11b and the third upper conductive part A22c may be formed by an influence of plasma during a process of forming the first open area OA1 and the second open area OA2.

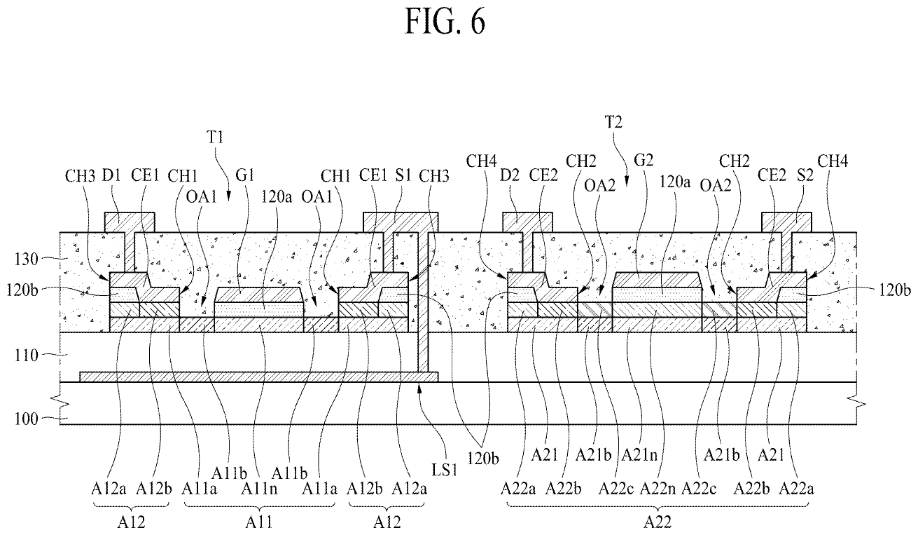

FIG. 6 is a cross-sectional view of a thin film transistor substrate according to another embodiment of the present disclosure, which is the same as the thin film transistor substrate according to FIG. 5 except that the second lower active layer A21 of the second thin film transistor T2 has a second lower conductive part A21b.

As shown in FIG. 6, the second lower active layer A21 further includes a second lower conductive part A21b.

The second lower conductive part A21b may be formed by the plasma influence when forming the third upper conductive part A22c of the second upper active layer A22 reaching the second lower active layer A21. Accordingly, the second lower conductive part A21b may be formed to overlap the third upper conductive part A22c.

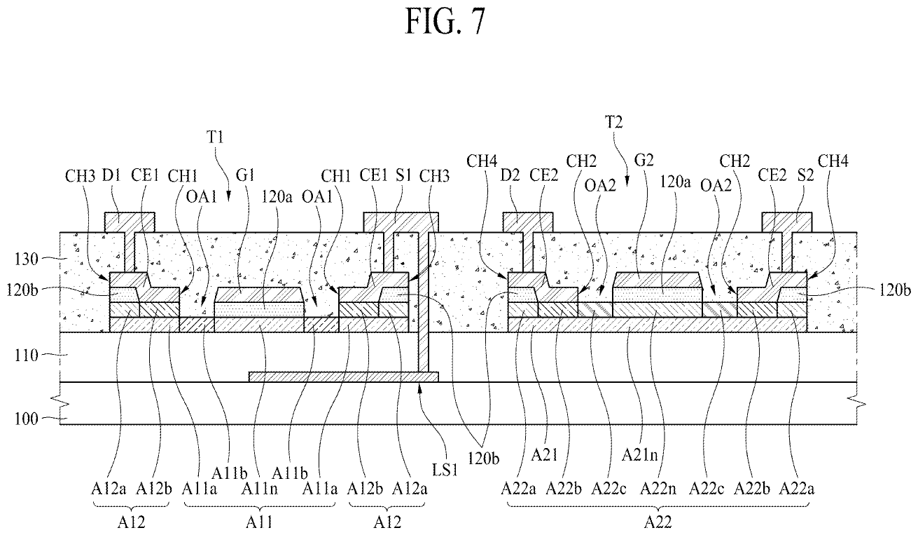

FIG. 7 is a cross-sectional view of a thin film transistor substrate according to another embodiment of the present disclosure. FIG. 7 is the same as the thin film transistor substrate according to FIG. 5, except that the structure of the first light blocking layer LS1 is changed.

As shown in FIG. 7, the first light shielding layer LS1 is provided to overlap a portion of the first active layers A11 and A12, without overlapping the entire first active layers A11 and A12.

Specifically, the first light shielding layer LS1 is overlapped with the one first lower conductive part A11b provided on one side, for example, the right side of the first channel part A11n and is not overlapped with the another first lower conductive part A11b provided on another side, for example, the left side of the first channel part A11n. Accordingly, an effective gate voltage VEFF applied to the one first lower conductive part A11b may be less than an effective gate voltage VEFF applied to the another first lower conductive part A11b, so that the S-factor of the first thin film transistor T1 may be increased.

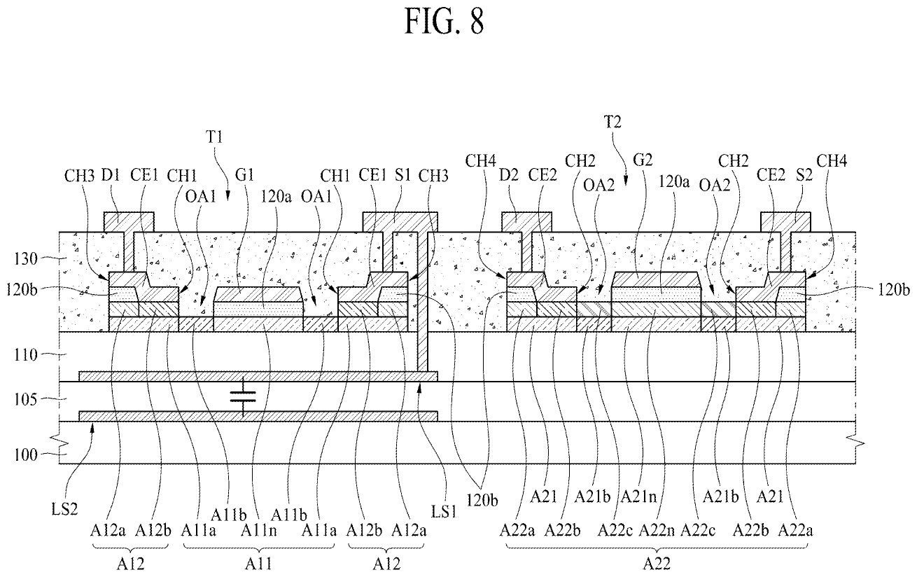

FIG. 8 is a cross-sectional view of a thin film transistor substrate according to another embodiment of the present disclosure. FIG. 8 is the same as the thin film transistor substrate according to FIG. 5 described above, except that a second light blocking layer LS2 and an additional buffer layer 105 are added.

As shown in FIG. 8, an additional buffer layer 105 is formed under the first light shielding layer LS1, and a second light shielding layer LS2 may be formed additionally under the additional buffer layer 105.

The second light shielding layer LS2 is made of a conductive material, and the capacitor is configured by the first light shielding layer LS1, the additional buffer layer 105, and the second light shielding layer LS2 to increase the capacitor capacity. Although not shown, the second light shielding layer LS2 can be electrically connected to the first gate electrode G1.

The first light shielding layer LS1 formed relatively above may be connected to the first source electrode S1, and the second light shielding layer LS2 formed relatively below may be connected to the first gate electrode G1, but in some cases, the first light shielding layer LS1 formed relatively above may be connected to the first gate electrode G1, and the second light shielding layer LS2 formed relatively below may be connected to the first source electrode S1.

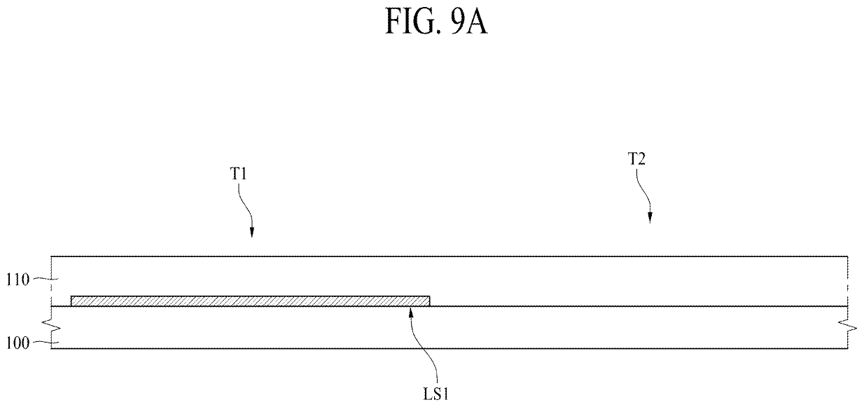

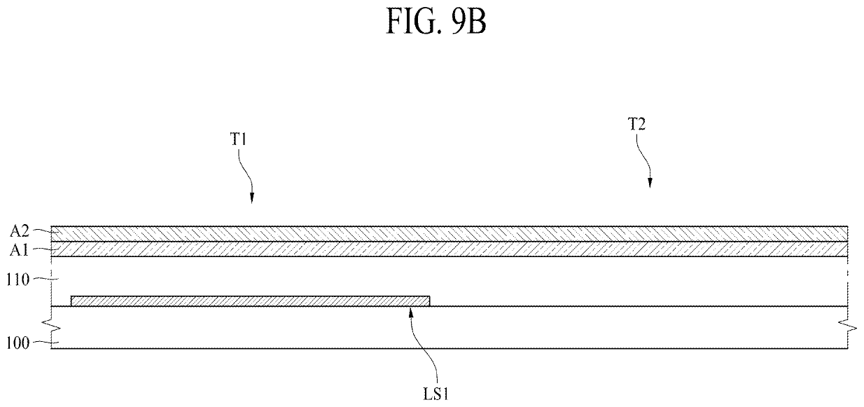

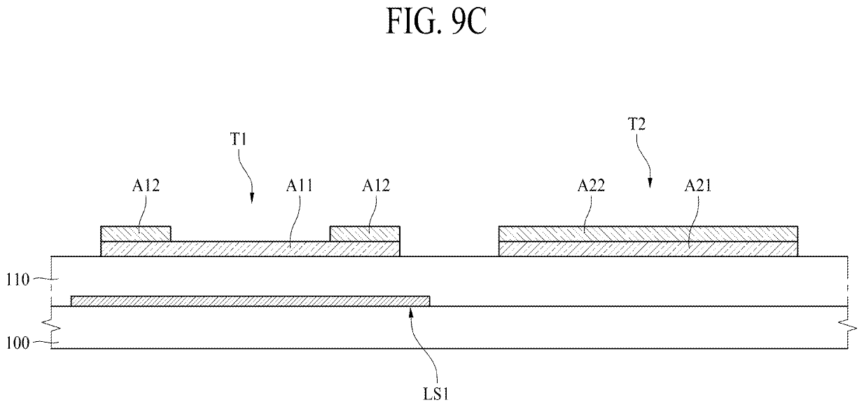

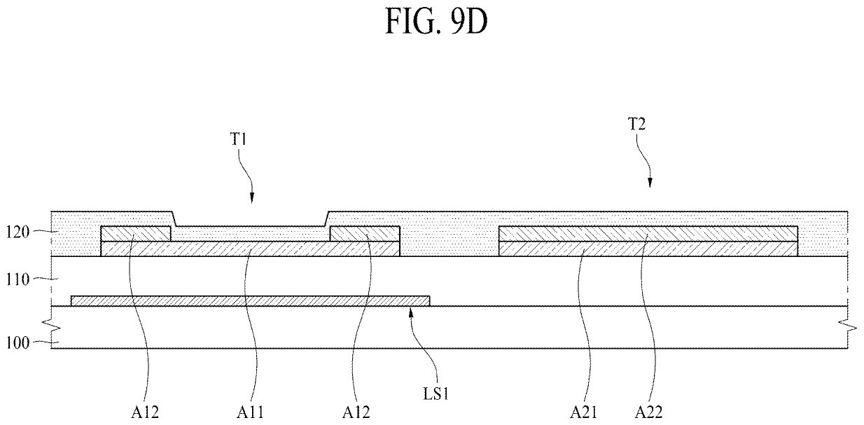

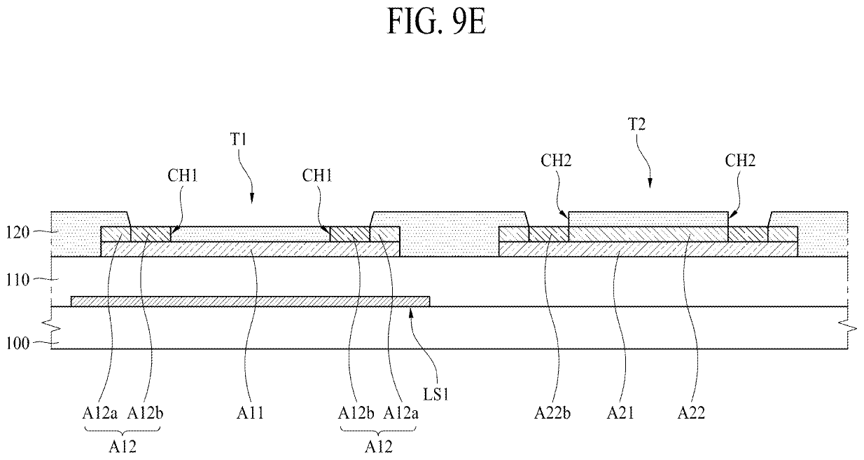

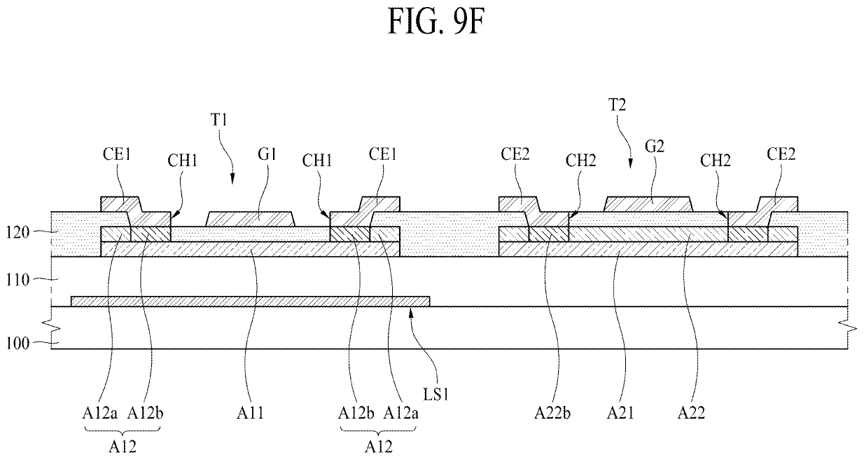

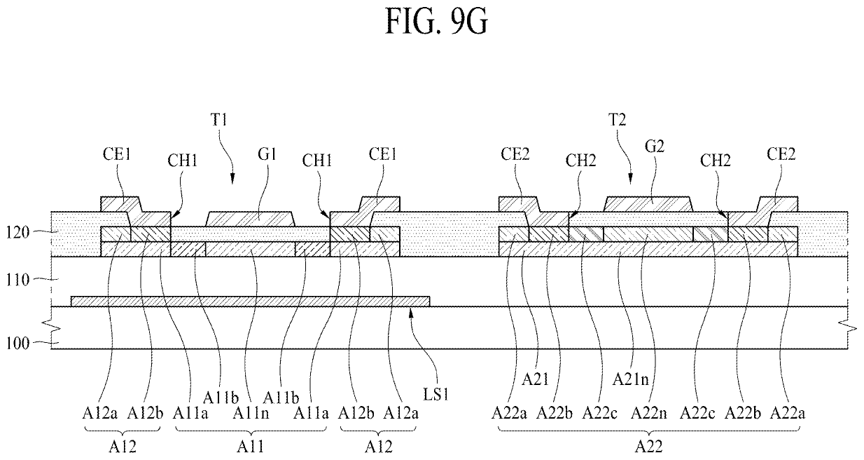

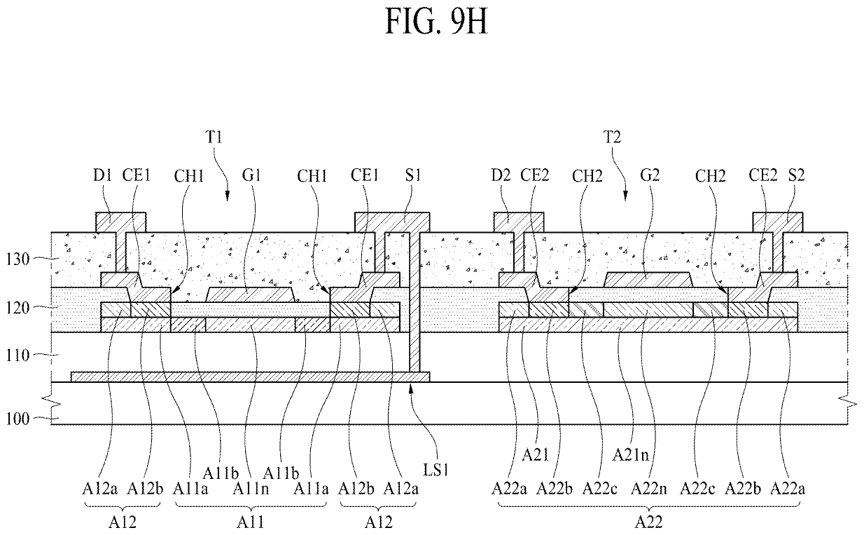

FIGS. 9A to 9H are cross-sectional views of a manufacturing process of a thin film transistor substrate according to an embodiment of the present disclosure, which relates to a manufacturing process of a thin film transistor substrate according to FIG. 1B described above.

First of all, as shown in FIG. 9A, a first light shielding layer LS1 is formed on a substrate 100, and a buffer layer 110 is formed on the first light shielding layer LS1.

The first light shielding layer LS1 is formed in the first thin film transistor T1 region and is not formed in the second thin film transistor T2 region. Meanwhile, when the length of the first light shielding layer LS1 is short, the thin film transistor substrate as shown in FIG. 3 may be obtained. In addition, when a second light shielding layer LS2 and an additional buffer layer 105 are additionally formed before the formation of the first light shielding layer LS1, a thin film transistor substrate as shown in FIG. 4 can be obtained.

Next, As shown in FIG. 9B, a lower active layer A1 and an upper active layer A2 are formed in turn on the buffer layer 110.

Next, as shown in FIG. 9C, the lower active layer A1 and the upper active layer A2 are patterned, and first active layers A11 and A12 of the first thin film transistor T1 and second active layer A21 and A22 of the second thin film transistor T2 are formed.

Specifically, in the first thin film transistor T1 region, the lower active layer A1 and the upper active layer A2 are patterned, and a first lower active layer A11 and first upper active layers A12 provided on one side and another side of the first lower active layer A11 are formed. In this case, the first lower active layer A11 and the first upper active layer A12 may be formed by a single exposure process using a halftone mask.

In addition, in the second thin film transistor T2 region, the lower active layer A1 and the upper active layer A2 are patterned, and the second lower active layer A21 and the second upper active layer A22 having the same pattern are formed.

Next, As shown in FIG. 9D, a gate insulating layer 120 is formed on the first active layers A11 and A12 and the second active layers A21 and A22.

Next, as shown in FIG. 9E, a first contact hole CH1 is formed in the first thin film transistor T1 by etching a portion of the gate insulating layer 120 while a second contact hole CH2 is formed in the second thin film transistor T2.

In this case, due to the influence of the plasma in the process of etching a portion of the gate insulating layer 120, a region of the first upper active layer A12 exposed by the first contact hole CH1 is conducted to form the first upper conductive part A12b, and a region of the first upper active layer A12 that is not exposed by the first contact hole CH1 becomes a first upper non-conductive part A12a.

In addition, due to the influence of plasma during the process of etching a portion of the gate insulating layer 120, a region of the second upper active layer A22 exposed by the second contact hole CH2 is conducted to form a second upper conductive part A22b.

Next, as shown in FIG. 9F, two first connection electrodes CE1 connected to the first upper conductive part A12b through the first contact hole CH1 in the first thin film transistor T1 region, and a first gate electrode G1 between the two first connection electrodes CE1 are formed. At the same time, two second connection electrodes CE2 connected to the second upper conductive part A22b through the second contact hole CH2 in the second thin film transistor T2 region, and second gate electrode G2 between the two second connection electrode CE2 are formed.

Next, as shown in FIG. 9G, an ion doping process is performed using the gate electrodes G1, G2 and the connection electrodes CE1 and CE2 as a mask.

In this way, in the first thin film transistor T1 region, impurities penetrate the separated area between the first gate electrode G1 and the first connection electrode CE1 to form the first lower conductor part A11b, A first channel part A11n in which impurities do not penetrate is formed by being covered by the first gate electrode G1, and a first connection part A11a in which impurities do not penetrate is formed by being covered by the first connection electrode CE1.

In addition, in the second thin film transistor T2 region, impurities penetrate the separated area between the second gate electrode G2 and the second connection electrode CE2 to form a third upper conductive part A22c, a second channel part A22n in which impurities do not penetrate is formed by being covered by the second gate electrode G2, and a second upper non-conductive part A22a in which impurities do not penetrate is formed by being covered by the second connection electrode CE2.

In addition, a second lower active layer A21, which includes a third channel part A21n in an area overlapping the second gate electrode G2, without impurities penetrating, can be completed.

On the other hand, although not shown, in the second thin film transistor T2 area, when impurities penetrated into the spaced area between the second gate electrode G2 and the second connection electrode CE2 penetrate the second lower active layer A21, a second lower conductive part A21b as shown in FIG. 2 may be additionally formed.

Next, as shown in FIG. 9H, an interlayer insulating layer 130 is formed on the gate electrodes G1, G2 and the connection electrodes CE1, CE2, and the first connection electrode CE1 and the second connection electrode CE2 is exposed by forming a contact hole in the interlayer insulating layer 130, and source electrodes S1 and S2 and drain electrode D1 and D2 is formed on the interlayer insulating layer 130.

In the first thin film transistor T1 region, the first source electrode S1 and the first drain electrode D1 are connected to the exposed first connection electrode CE1, and in the second thin film transistor T2 region, The second source electrode S2 and the second drain electrode D2 are connected to the exposed second connection electrode CE2.

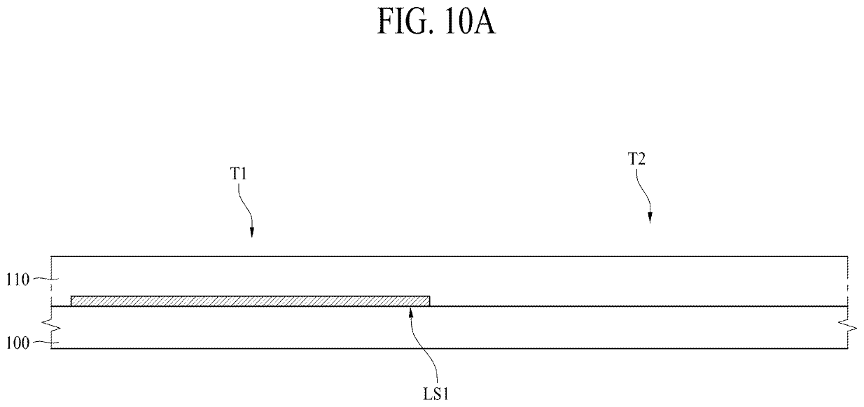

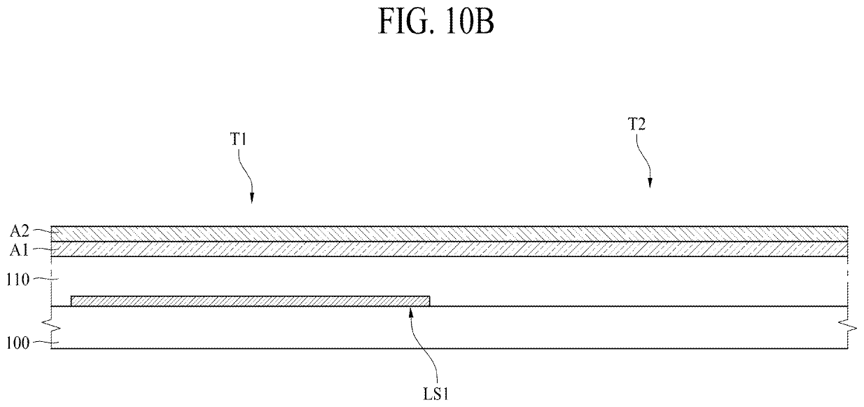

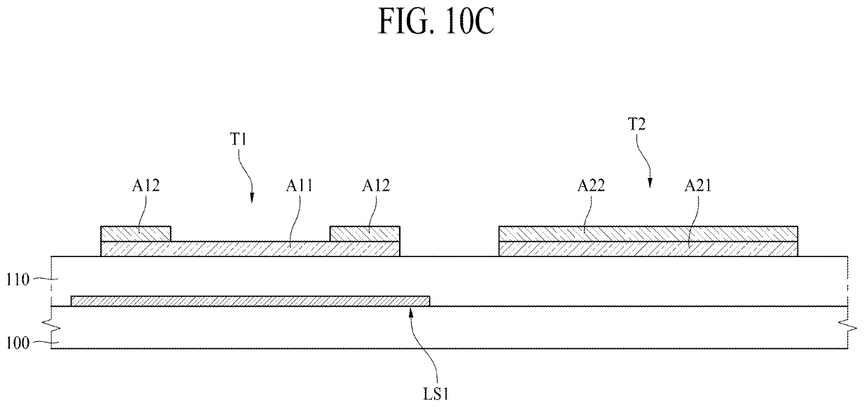

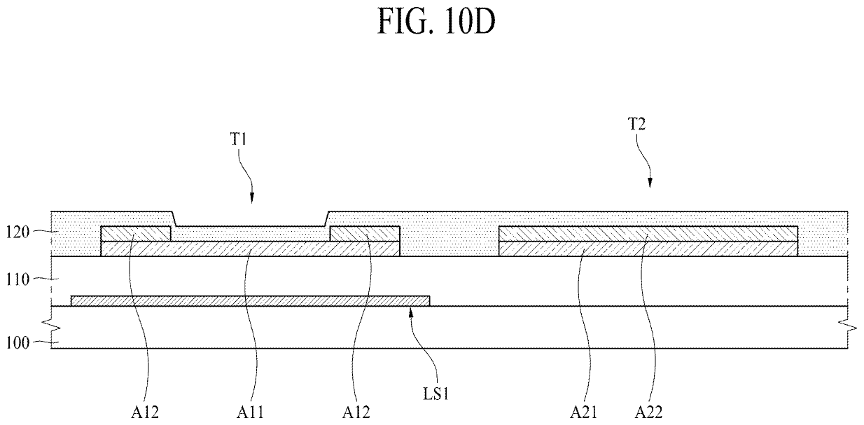

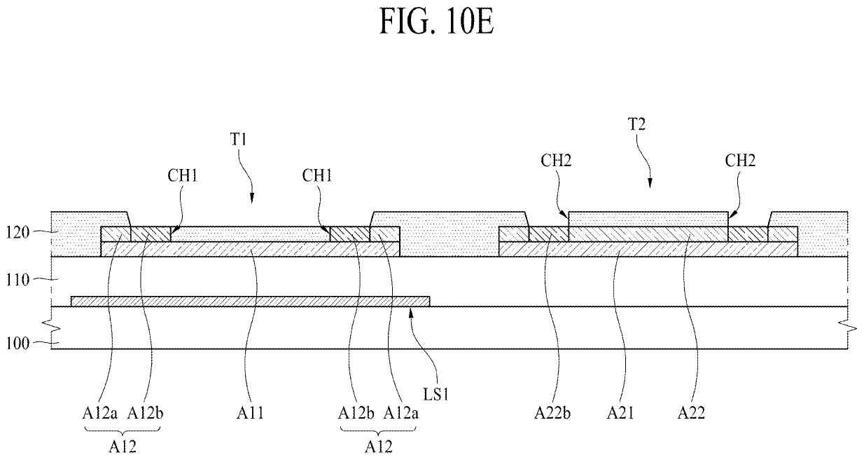

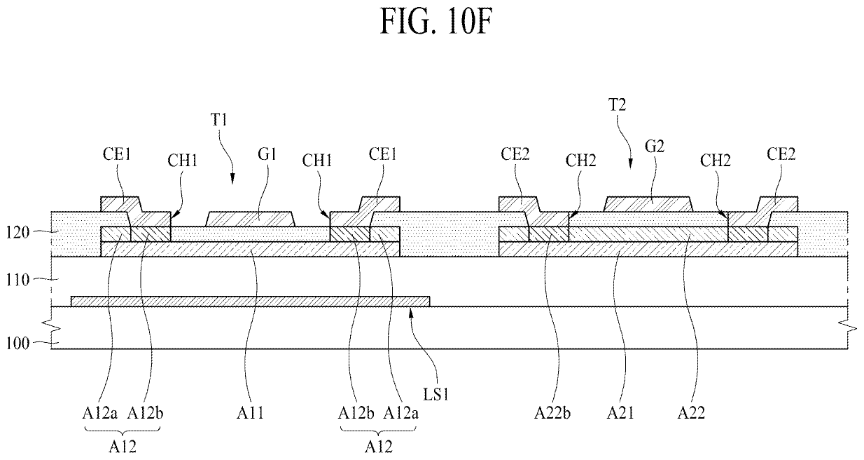

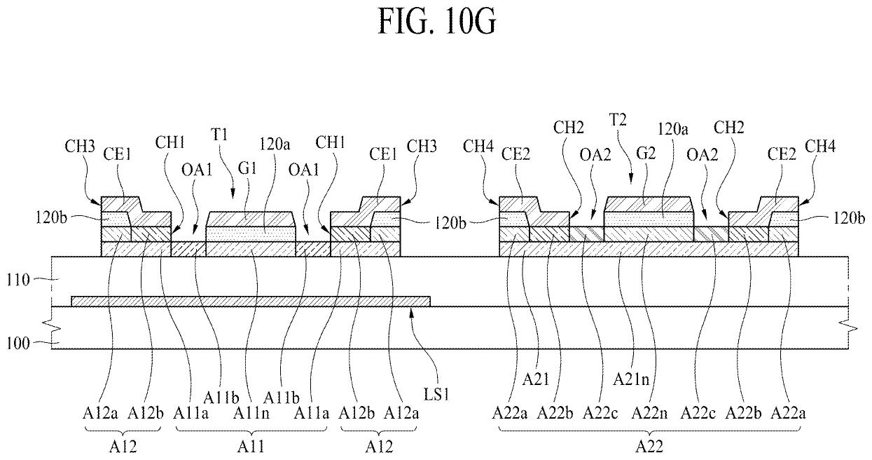

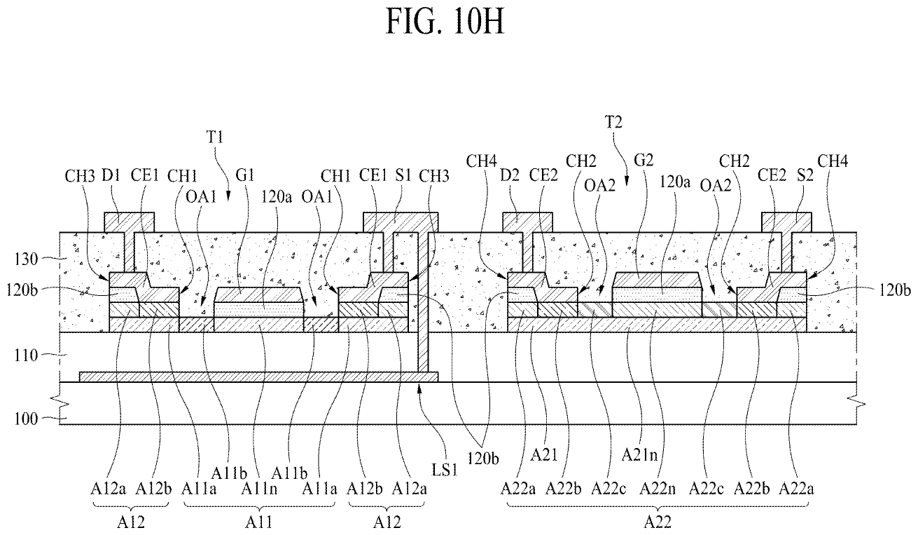

FIGS. 10A to 10H are cross-sectional views of a manufacturing process of a thin film transistor substrate according to another embodiment of the present disclosure, which relates to a manufacturing process of a thin film transistor substrate according to FIG. 5 described above.

First of all, As shown in FIG. 10A, a first light shielding layer LS1 is formed on a substrate 100, and a buffer layer 110 is formed on the first light shielding layer LS1. This process is the same as the process in FIG. 9A described above.

On the other hand, when the length of the first light shielding layer LS1 is formed shortly, the thin film transistor substrate according to FIG. 7 described above may be obtained. In addition, when the second light shielding layer LS2 and the additional buffer layer 105 are further formed before the first light shielding layer LS1 is formed, a thin film transistor substrate according to FIG. 8 as described above may be obtained.

Next, as shown in FIG. 10B, a lower active layer A1 and an upper active layer A2 are formed in turn on the buffer layer 110. This process is the same as the process according to FIG. 9B described above.

Next, as shown in FIG. 10C, the lower active layer A1 and the upper active layer A2 are patterned to form the first active layer A11 and A12 of the first thin film transistor T1 and the second active layers A21 and A22 of the second thin film transistor T2. This process is the same as the process according to FIG. 9C described above.

Next, As shown in FIG. 10D, a gate insulating layer 120 is formed on the first active layers A11 and A12 and the second active layers A21 and A22. This process is the same as the process according to FIG. 9D described above.

Next, as shown in FIG. 10E, a portion of the gate insulating layer 120 is etched to form the first contact hole CH1 in the first thin film transistor T1, and the second contact hole CH2 in the second thin film transistor T2 at the same time. This process is the same as the process according to FIG. 9E described above.

Next, as shown in FIG. 10F, in the first thin film transistor T1 region, two first connection electrodes CE1 connected to the first upper conductive part A12b through the first contact hole CH1, and a first gate electrode G1 between the two first connection electrodes CE1 are formed. At the same time, in the second thin film transistor T2 region, two second connection electrodes CE2 connected to the second upper conductive part A22b through the second contact hole CH2, and a second gate electrode G2 between the two second connection electrodes CE2 are formed. This process is the same as the process according to FIG. 9F described above.

Next, as shown in FIG. 10G, the gate insulating layer 120 is etched using the gate electrodes G1, G2 and the connection electrodes CE1 and CE2 as a mask.

Then a first gate insulating layer 120a which is not etched by being covered by the gate electrodes G1 and G2 is formed, and a second gate insulating layer 120b which is not etched by being covered by the connection electrodes CE1 and CE2 is formed.

In this case, a first open area OA1 obtained by removing the gate insulating layers 120a and 120b is formed in the spaced area between the first gate electrode G1 and the first connection electrode CE1, and a second open area OA2 obtained by removing the gate insulating layers 120a and 120b is formed in the spaced area between the second gate electrode G2 and the second connection electrode CE2.

In addition, a first lower conductive part A11b is formed in the first open area OA1 by the influence of the plasma during the etching process of the gate insulating layer 120, and a first channel part A11n that is not affected by plasma is formed by being covered by the first gate electrode G1, and a first connection part A11a that is not affected by plasma is formed by the first connection electrode CE1.

Similarly, by the influence of the plasma at the time of etching process of the gate insulating layer 120, a third upper conductive part A22c is formed in the second open area OA2, and a second channel part A22n that is not affected by plasma is formed by being covered by the second gate electrode G2, and a second upper non-conductive part A22a that is not affected by plasma is formed by being covered by the second connection electrode CE2.

In addition, a second lower active layer A21, which is not affected by plasma, can be formed while including a third channel part A21n in an area overlapping the second gate electrode G2.

On the other hand, although not illustrated, if the influence of plasma in the second open area OA2 reaches the second lower active layer A21 in the second thin film transistor T2 region, a second lower conductive part A21b as shown in FIG. 2 may be additionally formed.

Next, as shown in FIG. 10H, an interlayer insulating layer 130 is formed on the gate electrodes G1 and G2 and the connection electrodes CE1 and CE2, a contact hole is formed in the interlayer insulating layer 130 to expose the first connection electrode CE1 and the second connection electrode CE2, and source electrode S1 and S2 and drain electrodes D1 and D2 is formed on the interlayer insulating layer 130. This process is the same as the process according to FIG. 9H described above.

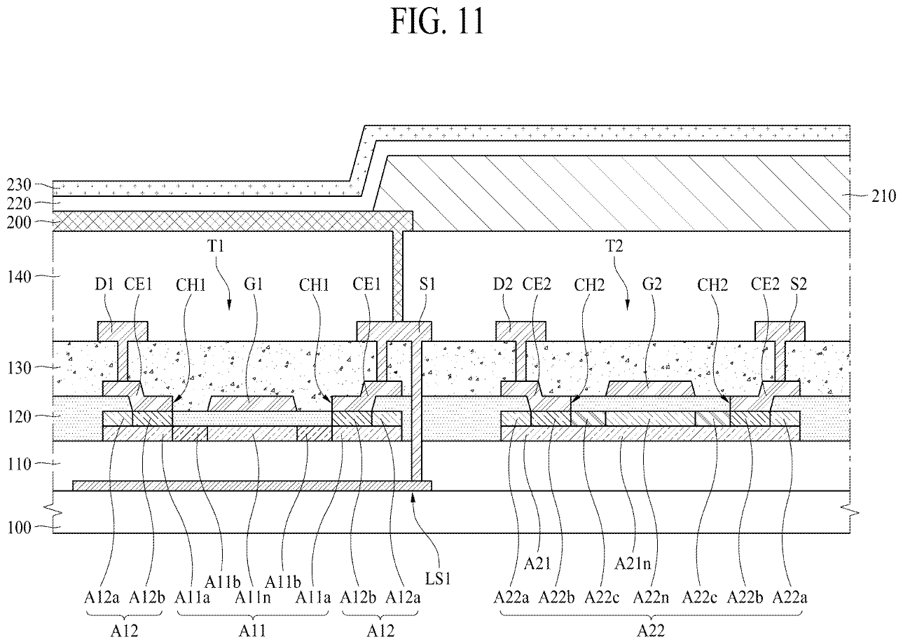

FIG. 11 is a cross-sectional view of a display apparatus according to an embodiment of the present disclosure.

As shown in FIG. 11, the display apparatus according to an embodiment of the present disclosure includes a thin film transistor substrate according to FIG. 1B described above, a planarization layer 140, a first electrode 200, a bank 210, a light emitting layer 220 and a second electrode 230.

Although FIG. 11 illustrates the thin film transistor substrate according to FIG. 1B described above, the thin film transistor substrate according to any one of FIGS. 2 to 8 described above may be applied.

The planarization layer 140 is formed on the first source electrode S1, the first drain electrode D1, the second source electrode S2, and the second drain electrode D2.

The first electrode 200 is provided on the planarization layer 140. The first electrode 200 may be connected to the first source electrode S1 through a contact hole provided in the planarization layer 140. The first electrode 200 may be connected to the first drain electrode D1. The first electrode 200 may function as an anode.

Although not shown, the first source electrode S1 and the first electrode 200 may not be connected directly, and may be electrically connected through a connection layer therebetween. In this case, the planarization layer 140 is formed of a two-layer structure of a lower planarization layer and an upper planarization layer, the connection layer is connected to the first source electrode S1 through a contact hole of the lower planarization layer, and the first electrode 200 is connected to the connection layer through a contact hole of the upper planarization layer.

The bank 210 is provided to cover the edge of the first electrode 200 to define the light emitting area. Therefore, an upper surface area of the first electrode 200, which is exposed without hidden by the bank 210, becomes the light emitting area.

The light emitting layer 220 is provided on the first electrode 200 and the bank 210. The light emitting layer 220 may consist of a red, green, and blue emission layer patterned for each pixel, or may consist of a white emission layer connected to all pixels. When the light emitting layer 220 is made of a white light emitting layer, the light emitting layer 200 may include, for example, a first stack including a blue light emitting layer, a second stack including a yellow green light emitting layer, and a charge generation layer provided between the first stack and the second stack, but is not limited thereto. When the light emitting layer 220 is formed of a white light emitting layer, a color filter is provided for each pixel.

The second electrode 230 is provided on the light emitting layer 220. The second electrode 230 may function as a cathode.

As shown in FIG. 11, a bank 210 is adjacent to the light emitting diode (200, 220, 230). Here, the first thin film transistor T1 is also adjacent to the second thin film transistor T2. The first thin film transistor T2 is electrically connected to the light emitting diode. The second thin film transistor T2 fully overlaps with the bank 210 from a plan view. The first thin film transistor T1, on the other hand, only partially overlaps with the bank 210 from a plan view. Further, first lower conductive part A11b does not overlap with the bank 210 from a plan view.

Although not shown, an additional encapsulation layer may be formed to prevent the penetration of moisture or oxygen on the second electrode 230.

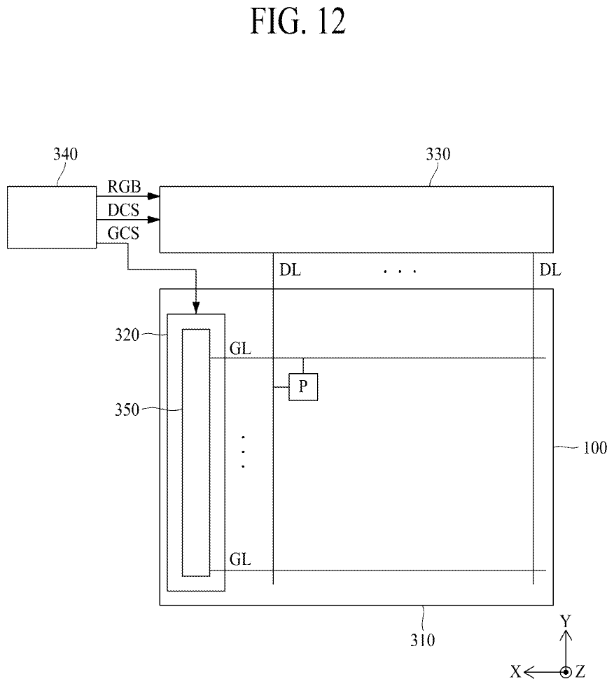

FIG. 12 is a schematic diagram of a display apparatus according to an embodiment of the present disclosure.

As shown in FIG. 12, the display apparatus according to an embodiment of the present disclosure may include a display panel 310, a gate driver 320, a data driver 330, and a controller 340.

The display panel 310 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100. The first thin film transistor T1 and the second thin film transistor T2 described above may be provided in the pixel P.

The controller 340 controls the gate driver 320 and the data driver 330. The controller 340 outputs a gate control signal GCS for controlling the gate driver 320 and a data control signal DCS for controlling the data driver 330 by using a signal supplied from an external system (not shown). Also, the controller 340 samples input video data input from the external system and rearranges the sampled input video data, and supplies the rearranged digital video data RGB to the data driver 330.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 330 supplies a data voltage to the data lines DL of the display panel 310. Specifically, the data driver 330 converts the video data RGB inputted from the controller 340 into an analog data voltage and supplies the data voltage to the data lines DL.

The gate driver 320 may be mounted on the display panel 310. As described above, a structure in which the gate driver 320 is directly mounted on the display panel 310 is referred to as a gate in panel (GIP) structure. Specifically, in the gate-in-panel (GIP) structure, the gate driver 320 may be disposed on the substrate 100. Among the first thin film transistor T1 and second thin film transistor T2 described above, the switching thin film transistor may be provided in the gate driver 320 having a gate in panel (GIP) structure.

The gate driver 320 may include a shift register 350.

The shift register 350 sequentially supplies gate pulses to the gate lines GL during one frame by the use of start signal and gate clock transmitted from the controller 340. Herein, the one frame refers to a period in which one image is outputted through the display panel 310. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal GS.

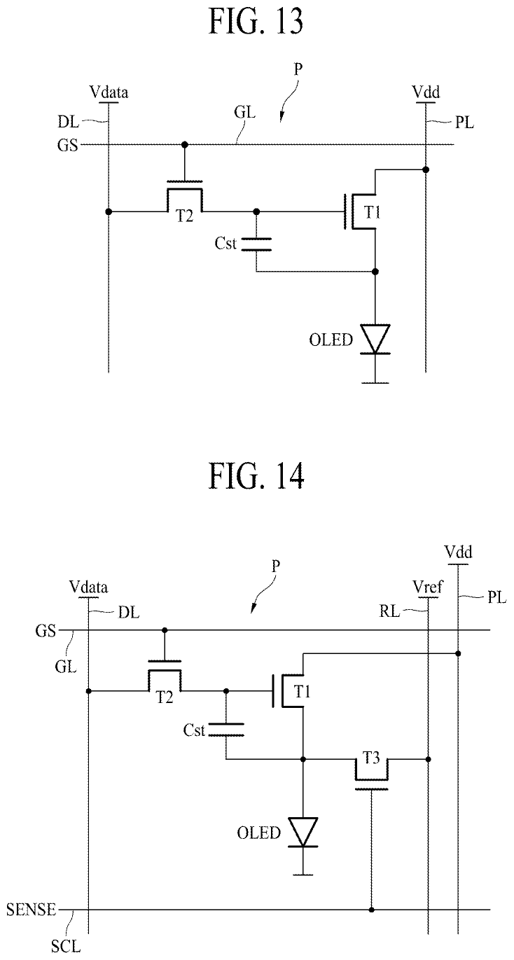

FIG. 13 is a circuit diagram of one pixel provided in a display apparatus according to an embodiment of the present disclosure.

As shown in FIG. 13, the display apparatus according to an embodiment of present disclosure includes first to second thin film transistors T1 and T2 and capacitors Cst.

The first thin film transistor T1 is a driving thin film transistor, and the second thin film transistor T2 is a switching thin film transistor. At least one of the first thin film transistor T1 and the second thin film transistor T2 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

FIG. 14 is a circuit diagram of one pixel provided in a display apparatus according to another embodiment of the present disclosure.

As shown in FIG. 14, the display apparatus according to another embodiment of present disclosure includes first to third thin film transistors T1, T2, T3 and a capacitor Cst.

The first thin film transistor T1 is a driving thin film transistor, and the second to third thin film transistors T2 to T3 are switching thin film transistors. At least one of the first to third thin film transistors T1, T2, and T3 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

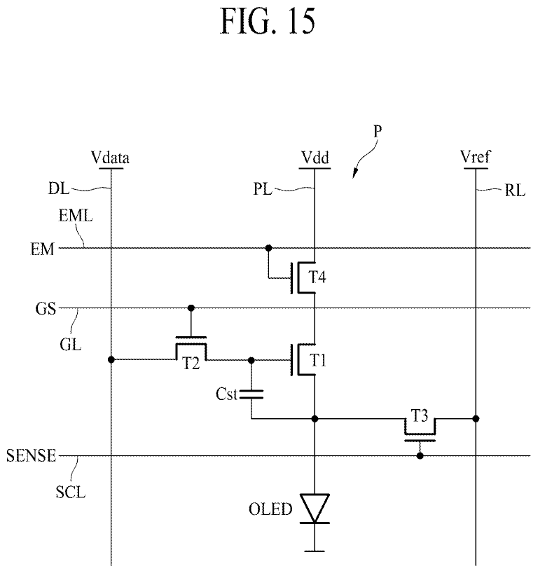

FIG. 15 is a circuit diagram of one pixel provided in a display apparatus according to another embodiment of the present disclosure.

As shown in FIG. 15, the display apparatus according to another embodiment of the present disclosure includes first to fourth thin film transistors T1, T2, T3, and T4 and a capacitor Cst.

The first thin film transistor T1 is a driving thin film transistor, and the second to fourth thin film transistors T2 to T4 are switching thin film transistors. At least one of the first to fourth thin film transistors T1, T2, T3, and T4 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The fourth thin film transistor T4 is switched according to the light emission control signal EM supplied to the light emission control line EML and supplies the driving voltage VDD supplied from the power line PL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

Accordingly, the present disclosure may have the following advantages.

According to an embodiment of present disclosure, since the first active layer includes a first lower active layer and a first upper active layer, and the first upper active layer is spaced apart from one side and another side of the first lower active layer, the first lower active layer may become the main channel of the carrier. In this case, as the carrier mobility of the semiconductor material constituting the first lower active layer is configured to be less than that of the semiconductor material constituting the first upper active layer, the S-factor of the first thin film transistor may increase as the carrier mobility in the main channel for moving the carrier is reduced, and accordingly, the first thin film transistor may be easily used as a driving thin film transistor.

According to an embodiment of present disclosure, since while the second active layer includes a second lower active layer and a second upper active layer, and the second upper active layer includes a second upper conductive part and a third upper conductive part relatively conductive, the second lower active layer does not include separate conductive part, the second upper active layer becomes the main channel of the electron. In this case, as the carrier mobility of the semiconductor material constituting the second upper active layer is configured to be greater than the carrier mobility of the semiconductor material constituting the second lower active layer, the on-current of the second thin film transistor may increase as the carrier mobility in the main channel of the carrier movement is increased, and accordingly, the second thin film transistor may be easily used as a switch thin film transistor.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor substrate comprising:
a substrate;
a first thin film transistor on the substrate, the first thin film transistor including a first gate electrode, a first active layer, a first source electrode, and a first drain electrode; and
a second thin film transistor on the substrate, the second thin film transistor including a second gate electrode, a second active layer with a pattern different from a pattern of the first active layer, a second source electrode, and a second drain electrode,
wherein the first active layer includes a first lower active layer overlapping the first gate electrode and a first upper active layer on the first lower active layer and not overlapping the first gate electrode, and
wherein the second active layer includes a second lower active layer overlapping the second gate electrode and a second upper active layer on the second lower active layer and overlapping the second gate electrode.

2. The thin film transistor substrate according to claim 1,
wherein the first lower active layer includes a same semiconductor material as the second lower active layer and is disposed on a same layer as the second lower active layer, and
wherein the first upper active layer includes a same semiconductor material as the second upper active layer and is on the same layer as the second upper active layer.

3. The thin film transistor substrate according to claim 1, further comprising:
a gate insulating layer between the first gate electrode and the first active layer,
a first contact hole included in the gate insulating layer exposing the first upper active layer, and
wherein the first upper active layer includes a first upper conductive part in a portion exposed by the first contact hole.

4. The thin film transistor substrate according to claim 3, further comprising:
a first connection electrode on the gate insulating layer and coupled to the first upper conductive part,
wherein the first connection electrode includes a same material as the first gate electrode.

5. The thin film transistor substrate according to claim 4,
wherein at least a portion of the first connection electrode is on a same layer as the first gate electrode, and
wherein the first connection electrode is coupled to the first source electrode or the first drain electrode.

6. The thin film transistor substrate according to claim 4,
wherein the gate insulating layer includes a first gate insulating layer overlapping the first gate electrode and a second gate insulating layer overlapping the first connection electrode, and
wherein the first gate insulating layer and the second gate insulating layer are spaced apart from each other.

7. The thin film transistor substrate according to claim 1,
wherein the first lower active layer includes a first channel part overlapping the first gate electrode, a first connection part overlapping the first upper active layer, and a first lower conductive part disposed between the first channel part and the first connection part.

8. The thin film transistor substrate according to claim 1, further comprising:
a gate insulating layer between the second gate electrode and the second active layer,
wherein the gate insulating layer includes a second contact hole exposing the second upper active layer, and
wherein the second upper active layer includes a second upper conductive part in a portion exposed by the second contact hole.

9. The thin film transistor substrate according to claim 8,
wherein the second upper active layer includes a second channel part overlapping the second gate electrode, and a third upper conductive part between the second channel part and the second upper conductive part.

10. The thin film transistor substrate according to claim 8, further comprising:
a second connection electrode on the gate insulating layer and coupled to the second upper conductive part,
wherein the second connection electrode includes a same material as the first gate electrode.

11. The thin film transistor substrate according to claim 8,
wherein the second lower active layer includes a second lower conductive part in a region overlapping the third upper conductive part.

12. The thin film transistor substrate according to claim 1,
wherein the second lower active layer includes a third channel part in a region overlapping the second gate electrode.

13. The thin film transistor substrate according to claim 1, further comprising:
a first light shielding layer coupled to the first source electrode, disposed below the first active layer, and overlapping the first active layer.

14. The thin film transistor substrate according to claim 13,
wherein the first light shielding layer does not overlap a portion of the first active layer.

15. The thin film transistor substrate according to claim 13, further comprising:
a second light shielding layer disposed below the first active layer and constituting a capacitor along with the first light shielding layer.

16. The thin film transistor substrate according to claim 1,
wherein the first gate electrode and the second gate electrode are made of a same material on a same layer, and
wherein the first source electrode, the first drain electrode, the second source electrode, and the second drain electrode are made of a same material on a same layer.

17. A thin film transistor substrate comprising:
a substrate;
a first thin film transistor on the substrate, the first thin film transistor including a first gate electrode, a first active layer, a first source electrode, and a first drain electrode; and
a second thin film transistor on the substrate, the second thin film transistor including a second gate electrode, a second active layer with a pattern different from a pattern of the first active layer, a second source electrode, and a second drain electrode,
wherein the first active layer includes a first lower active layer and two first upper active layers disposed to be spaced apart from each other on one side and another side of the first lower active layer, and
wherein the second active layer includes a second lower active layer and a second upper active layer on the second lower active layer and having a same shape as the second lower active layer.

18. The thin film transistor substrate according to claim 17,
wherein the first lower active layer and the second lower active layer include a same semiconductor material,
wherein the first upper active layer and the second upper active layer include a same semiconductor material, and
wherein a carrier mobility of each of the first upper active layer and the second upper active layer is greater than a carrier mobility of each of the first lower active layer and the second lower active layer.

19. The thin film transistor substrate according to claim 18,
wherein the first upper active layer and the second upper active layer include at least one of an IGZO (InGaZnO)-based oxide semiconductor material, an IZO (InZnO)-based oxide semiconductor material, an IGZTO(InGaZnSnO)-based oxide semiconductor material, an ITZO(InSnO)-based oxide semiconductor material, a FIZO(FeInZnO)-based oxide semiconductor material, a ZnO-based semiconductor material, a SIZO(SiInZnO)-based oxide semiconductor material, and a ZnON(Zn-Oxynitride)-based oxide semiconductor material,
wherein the first lower active layer and the second lower active layer include at least one of an IGZO(InGaZnO)-based oxide semiconductor material, a GZO(GaZnO)-based oxide semiconductor material, an IGO(InGaZnO)-based oxide semiconductor material, and a GZTO(GaZnSnO)-based oxide semiconductor material, and
when the first upper active layer, the second upper active layer, the first lower active layer, and the second lower active layer are made of IGZO(InGaZnO)-based oxide semiconductor materials, a concentration of indium (In) of the first and second upper active layers is greater than a concentration of indium (In) of the first and second lower active layers.

20. The thin film transistor substrate according to claim 17,
wherein the first upper active layer includes a first upper conductive part,
wherein the first lower active layer includes a first channel part overlapping the first gate electrode, a first connection part overlapping the first upper active layer, and a first lower conductive part between the first channel part and the first connection part,
wherein the second upper active layer includes a second channel part overlapping the second gate electrode, a second upper conductive part on one side of the second channel part, and a third upper conductive part between the second channel part and the second upper conductive part, and
wherein the second lower active layer includes a third channel part overlapping the second gate electrode.

21. The thin film transistor substrate according to claim 20,
wherein the first upper conductive part is in contact with the first lower conductive part.

22. The thin film transistor substrate according to claim 20,
wherein the first upper active layer further includes a first upper non-conductive part coupled to the first upper conductive part, and
wherein the second upper active layer further includes a second upper non-conductive part coupled to the second upper conductive part.

23. The thin film transistor substrate according to claim 20, further comprising:
a first connection electrode coupled to the first upper conductive part and a second connection electrode coupled to the second upper conductive part,
wherein the first connection electrode, the second connection electrode, the first gate electrode, and the second gate electrode are made of a same material.

24. A method of manufacturing a thin film transistor substrate comprising:
a process of sequentially forming a lower active layer and an upper active layer on a substrate;
a process of forming a first active layer of a first thin film transistor and a second active layer of a second thin film transistor by patterning the lower active layer and the upper active layer;
a process of forming a gate insulating layer on the first active layer and the second active layer;
a process of etching a portion of the gate insulating layer to form a first contact hole exposing a portion of the first active layer and a second contact hole exposing a portion of the second active layer; and
a process of forming a first gate electrode overlapping the first active layer, a second gate electrode overlapping the second active layer, a first connection electrode connected to the first active layer through the first contact hole, and a second connection electrode connected to the second active layer through the second contact hole on the gate insulating layer,
wherein the process of forming the first active layer includes a process of forming a first lower active layer and two first upper active layers to be spaced apart from each other on one side and another side of the first lower active layer, and
wherein the process of forming the second active layer includes a process of forming a second lower active layer and a second upper active layer in a same shape as the second lower active layer on the second lower active layer.

25. The method of manufacturing the thin film transistor substrate according to claim 24,
wherein the process of forming the first contact hole includes a process of exposing a portion of the two first upper active layers and forming a first upper conductive part in the portion of the exposed first upper active layer, and
wherein the process of forming the second contact hole includes exposing a portion of the second upper active layer and forming a second upper conductive part in the portion of the exposed second upper active layer.

26. The method of manufacturing the thin film transistor substrate according to claim 24, further comprising:
after the process of forming the first gate electrode, the second gate electrode, the first connection electrode, and the second connection electrode,
a process of forming a first lower conductive part in the first lower active layer area overlapping a separation area between the first gate electrode and the first connection electrode, and
a process of forming a third upper conductive part in the second upper active layer area overlapping a separation area between the second gate electrode and the second connection electrode.

27. The method of manufacturing the thin film transistor substrate according to claim 26,
wherein the process of forming the third upper conductive part further includes a process of forming a second lower conductive part in the second lower active layer area overlapping the third upper conductive part.

28. The method of manufacturing the thin film transistor substrate according to claim 26, further comprising:
after the process of forming the first lower conductive part and the process of forming the third upper conductive part,
a process of forming an interlayer insulating layer on the first gate electrode, the second gate electrode, the first connection electrode, and the second connection electrode, and exposing portions of the first connection electrode and the second connection electrode, and
a process of forming a first source electrode connected to the first connection electrode and a second source electrode connected to the second connection electrode on the interlayer insulating layer.
